(19) United States
(12) Patent Application Publication
(10) Pub. No.: US 2015/0129864 A1
(43) Pub. Date: May 14, 2015

(54) ORGANIC-INORGANIC HYBRID TRANSISTOR

(71) Applicant: E Ink Holdings Inc., Hsinchu (TW)

(72) Inventors: Cheng-Hang HSU, HSINCHU (TW); Hsing-Yi WU, HSINCHU (TW); Chia-Chun YEH, HSINCHU (TW); Ted-Hong SHINN, HSINCHU (TW)

(21) Appl. No.: 14/296,440

(22) Filed: Jun. 4, 2014

(30) Foreign Application Priority Data
Nov. 8, 2013 (TW) 102140780

(51) Int. Cl. H01L 29/786; H01L 29/51

(52) U.S. Cl. CPC H01L 29/78693; H01L 29/51
USPC 257/43

(57) ABSTRACT

An organic-inorganic hybrid transistor comprises a flexible substrate, a gate electrode, an organic gate dielectric layer, an oxide semiconductor layer, a first passivation layer, a source electrode and a drain electrode. The gate electrode is disposed on the flexible substrate. The organic gate dielectric layer covers the gate electrode and a portion of the flexible substrate. The oxide semiconductor layer is disposed over the organic gate dielectric layer. The first passivation layer is interposed between and in contact with the oxide semiconductor layer and the organic gate dielectric layer. The source electrode and the drain electrode are respectively connected to different sides of the oxide semiconductor layer.

### PRIORITY CLAIM AND CROSS-REFERENCE

This application claims priority to Taiwanese application Serial Number 102140780, filed Nov. 8, 2013, the entirety of which is incorporated herein by reference.

### BACKGROUND

1. Technical Field

The present disclosure relates to an organic-inorganic hybrid transistor, and particularly to an organic-inorganic hybrid oxide semiconductor thin film transistor.

2. Description of Related Art

With rapid progress in display technologies, LCD, mobile phones, notebooks as well as digital cameras have become important electronic products in market. These electronic products all come with display panels that perform as medium to display images. In recent years, many researchers have been devoted to developing flexible display panels in order to broaden the application of display devices. However, there are many difficulties in the process when manufacturing flexible display panels. For example, glass substrates and inorganic materials are applied in most conventional manufacturing processes which may not be suitable for organic materials. Besides, some researchers also have worked on polymeric semiconductor materials. However, the carrier mobility of polymeric semiconductor material is far lower than that of oxide semiconductors, and further the manufacturing cost of the polymeric semiconductor is relatively expensive. These technical issues inhibit the improvement and the application of flexible display panels, and therefore there is a need for an improved semiconductor component which would improve the above-mentioned issues.

### SUMMARY

According to one aspect of the present disclosure, an organic-inorganic hybrid transistor is provided. The organic-inorganic hybrid transistor, particularly an oxide semiconductor thin-film transistor, may be formed on a flexible substrate, and the organic-inorganic hybrid transistor possesses an excellent reliability and practicality. According to various embodiments, the organic-inorganic hybrid transistor includes a flexible substrate, a gate electrode, an organic gate dielectric layer, an oxide semiconductor layer, a first passivation layer a source electrode and a drain electrode. The gate electrode is disposed on the flexible substrate. The organic gate dielectric layer covers the gate electrode and a portion of the flexible substrate. The oxide semiconductor layer is disposed over the organic gate dielectric layer, in which the oxide semiconductor layer overlaps the gate electrode when viewed in a direction vertical to the flexible substrate. The first passivation layer includes an inorganic material, and the first passivation layer is interposed between and in contact with the oxide semiconductor layer and the organic gate dielectric layer. The source electrode and the drain electrode are respectively connected to two different sides of the oxide semiconductor layer.

In one embodiment, the first passivation layer includes at least one material selected from the group consisting of aluminum oxide, silicon oxide, silicon nitride and a combination thereof.

In one embodiment, the first passivation layer is about 100 Angstrom (A) to about 1000 Angstrom (A) in thickness.

In one embodiment, the first passivation layer includes a material of sol-gel glass.

In one embodiment, the first passivation layer and the oxide semiconductor layer have a substantially identical pattern.

In one embodiment, the first passivation layer thoroughly covers the organic gate dielectric layer.

In one embodiment, the organic-inorganic hybrid transistor further comprises a second passivation layer disposed on and in contact with the source electrode, the drain electrode and the oxide semiconductor layer, in which the second passivation layer comprises an inorganic material.

In one embodiment, the organic-inorganic hybrid transistor further comprises an organic protective layer covering the second passivation layer.

In one embodiment, the second passivation layer comprises at least one material selected from the group consisting of aluminum oxide, silicon oxide, silicon nitride and a combination thereof.

In one embodiment, the first passivation layer and the second passivation layer comprise aluminum oxide, and the first passivation layer and the second passivation layer are respectively about 100 Angstrom (A) to about 1000 Angstrom (A) in thickness.

According to yet some embodiment, an organic-inorganic hybrid transistor comprises a flexible substrate, a source electrode, a drain electrode, a first passivation layer, an oxide semiconductor layer, a gate electrode, an organic gate dielectric layer. The source and drain electrodes are disposed on the flexible substrate. The first passivation layer is in contact with and disposed on the source electrode, the drain electrode and the flexible substrate, in which the first passivation layer has a first opening and a second opening respectively exposing a portion of the source electrode and a portion of the drain electrode. The oxide semiconductor layer is disposed on the first passivation layer. The exposed portion of the source electrode and the exposed portion of the drain electrode are respectively connected to two different sides of the oxide semiconductor layer. The gate electrode is disposed over the oxide semiconductor layer. The organic gate dielectric layer is interposed between the gate electrode and the oxide semiconductor layer.

In one embodiment, the organic-inorganic hybrid transistor further comprises a second passivation layer disposed between the organic gate dielectric layer and the oxide semiconductor layer. The second passivation layer covers the oxide semiconductor layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view schematically illustrating an organic-inorganic hybrid transistor according to various embodiments of the present disclosure.

FIG. 2 is a top view schematically illustrating the first passivation layer, the gate electrode and the gate line according to one embodiment of the present disclosure.

FIG. 3 is a cross-sectional view schematically illustrating an organic-inorganic hybrid transistor according to various embodiments of the present disclosure.

FIG. 4 is a cross-sectional view schematically illustrating an organic-inorganic hybrid transistor according to some embodiments of the present disclosure.

FIG. 5 is a cross-sectional view schematically illustrating an organic-inorganic hybrid transistor according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

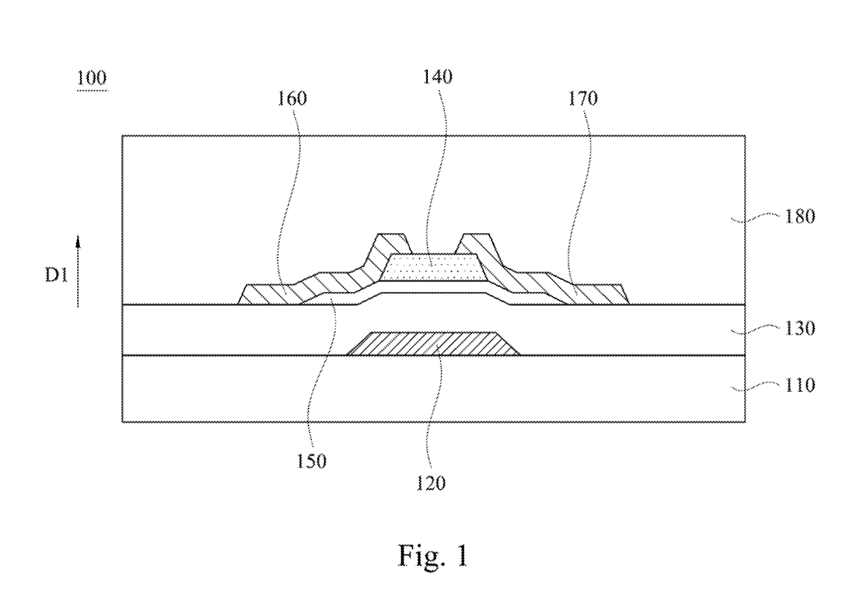

FIG. 1 is a cross-sectional view schematically illustrating an organic-inorganic hybrid transistor 100 according to various embodiments of the present disclosure. The organic-inorganic hybrid transistor 100 comprises a flexible substrate 110, a gate electrode 120, an organic gate dielectric layer 130, an oxide semiconductor layer 140, a first passivation layer 150, a source electrode 160 and a drain electrode 170.

The flexible substrate 110 is used to carry the components formed thereon. In some embodiments, when an external force is applied onto the flexible substrate 110, the flexible substrate 110 may have an elastic bent deformation, and may recover to its original state when the external force is removed. According to some embodiments of the present disclosure, the organic-inorganic hybrid transistor 100 may be applied to flexible electronic devices such as flexible display devices. Suitable materials for the flexible substrate 110 comprise, but are not limited to, polyimide, polyethylene terephthalate (PET), ethylene naphthalate (PEN) or the like. One skilled in the art would appreciate that the material of the flexible substrate 110 is not limited to these described hereinbefore. In some embodiments, the flexible substrate 110 may be a flexible glass substrate with a thickness of thinner than 100 μm (i.e. ultra-thin flexible glass).

The gate electrode 120 is disposed on the flexible substrate 110. The gate electrode 120 may be a single-layered structure or multiple-layered structure. The illustrative materials of the gate electrode 120 comprise platinum, gold, nickel, aluminum, molybdenum, copper, neodymium, chromium, an alloy thereof or a combination thereof. In addition, photolithography processes may be utilized to form the pattern of the gate electrode 120, for example. In some embodiments, heavily doped p-type silicon may be employed as the material of the gate electrode 120.

The organic gate dielectric layer 130 covers the gate electrode 120 and prevents the gate electrode 120 from direct contact with the oxide semiconductor layer 140, the source electrode 160 and the drain electrode 170. The organic gate dielectric layer 130 also covers at least a portion of the flexible substrate 110. Furthermore, the organic gate dielectric layer 130 is flexible as well. When flexible substrate 110 is bent and has a bent deformation, the organic gate dielectric layer 130 is bent as the flexible substrate 110 dose. It is needed to provide a strong adhesion between the organic gate dielectric layer 130 and the flexible substrate 110. When the flexible substrate 110 is bent, the organic gate dielectric layer 130 is able to remain attached to the flexible substrate 110 without peeling off. The organic gate dielectric layer 130 may be made of materials such as for example polyimide, fluoride amorphous carbon film, polyvinyl pyrrolidone, cyanate ester, polytetrafluo-roethylene (PTFE) or the like.

The oxide semiconductor layer 140 is disposed over the organic gate dielectric layer 130 and functions as the active layer of the thin film transistor 100. In some embodiments, the oxide semiconductor layer 140 comprises amorphous indium-gallium-zinc oxide (a-IGZO), indium zinc oxide (IZO) or amorphous indium-zinc-tin oxide (a-IZTO).

The first passivation layer 150 is interposed between the oxide semiconductor layer 140 and the organic gate dielectric layer 130, and the first passivation layer 150 is in contact with the oxide semiconductor layer 140 and the organic gate dielectric layer 130. Specifically, prior to forming the oxide semiconductor layer 140, the first passivation layer 150 is firstly formed on the organic gate dielectric layer 130. The first passivation layer 150 is used to protect the organic gate dielectric layer 130 from being damaged by the chemicals or the harsh condition during the formation of the oxide semiconductor layer 140. More detailed description is provided hereinafter. The material of the first passivation layer 150 is different from that of the oxide semiconductor layer 140 and the organic gate dielectric layer 130. The first passivation layer 150 is a passivation layer substantially made of inorganic material. The term “inorganic material” used herein, by meaning, comprises the inorganic material used in general chemistry field, and further comprises the glass film or ceramic film formed through sol-gel processes, i.e. sol-gel glass or sol-gel ceramics. These sol-gel glass or sol-gel ceramics may contain some organic materials.

According to some embodiments of the present disclosure, the first passivation layer 150 comprises aluminum oxide, silicon oxide, silicon nitride or a combination thereof. The first passivation layer 150 may be a single-layered or multiple-layered structure. In one example, the first passivation layer 150 is a single layer of aluminum oxide. In another example, the first passivation layer 150 is a double-layered structure having a silicon oxide layer and a silicon nitride layer, in which the silicon oxide layer is interposed between the oxide semiconductor layer 140 and the silicon nitride layer. In still another example, the first passivation layer 150 is a multiple-layered structure including an aluminum oxide layer and a silicon oxide layer, in which either the aluminum oxide layer or the silicon oxide layer is in contact with the oxide semiconductor layer 140. In other examples, the first passivation layer 150 is a double-layered structure consisting of an aluminum oxide layer and a silicon nitride layer, in which the aluminum oxide layer is interposed between the oxide semiconductor layer 140 and the silicon nitride layer.

According to yet some embodiments of the present disclosure, the first passivation layer 150 comprises a layer of sol-gel glass and/or sol-gel ceramic. For example, the sol-gel glass and/or sol-gel ceramic comprise boron-phosphor-silicate glass (BPSG), high silicon-content CaO-P₂O₅—SiO₂ glass or the like formed through the sol-gel process.

In some embodiments, when the thickness of the first passivation layer 150 is less than a certain value, for example, less than about 100 Angstrom (A), the first passivation layer 150 may not efficiently protect the organic gate dielectric layer 130. To the contrary, in some embodiments of the present disclosure, if the thickness of the first passivation layer 150 is greater than a certain thickness, for example, greater than about 2000 Angstrom (A), the first passivation layer 150 is broken and leads to the failure of the transistor 100 when the flexible substrate 110 is bent. Therefore, according to some embodiments of the present disclosure, the first passivation layer 150 is about 100 Angstrom (A) to about 2000 Angstrom (A) in thickness, specifically, about 100 Angstrom (A) to about 1000 Angstrom (A), more specifically, about 200 Angstrom (A) to about 800 Angstrom (A).

In yet some embodiments, the first passivation layer 150 has an island-shaped pattern as depicted in FIG. 1. According to one example of the present disclosure, when viewed in a direction D1 vertical to the flexible substrate 110, the first passivation layer 150 overlaps the gate electrode 120 and the oxide semiconductor layer 140, and the width (or the area) of the first passivation layer 150 is greater than that of the gate electrode 120.

Although FIG. 1 depicts that the width of the passivation layer 150 is greater than the gate electrode 120, the present disclosure is not limited thereto. In some embodiments, the pattern of the first passivation layer 150 is substantially identical to that of the oxide semiconductor layer 140. Particularly, an inorganic protective layer is firstly blanketly deposited on the organic gate dielectric layer 130, and then an oxide semiconductor layer is deposited on the inorganic protective layer. Afterwards, the inorganic passivation layer and the oxide semiconductor layer are patterned to form the first passivation layer 150 and the oxide semiconductor layer 140 by utilizing a single step of photolithographic-etching process. As a result, the first passivation layer 150 and the oxide semiconductor layer 140 have substantially the same pattern.

The source electrode 160 and drain electrode 170 are respectively connected to two different sides of the oxide semiconductor layer 140. The source electrode 160 and drain electrode 170 may be formed by approaches such as sputtering techniques, pulse laser vapor deposition, electron beam evaporation and chemical vapor deposition. The source electrode 160 and the drain electrode 170 may comprise metallic materials such as for example platinum, gold, nickel, aluminum, molybdenum, copper, neodymium or a combination thereof.

In one embodiment, the transistor 100 further comprises an organic protective layer 180. The organic protective layer 180 is disposed over the source electrode 160, drain electrode 170 and oxide semiconductor layer 140. The illustrative materials of the organic protective layer 180 comprise polyimide, fluoride amorphous carbon film, polyvinyl pyrrolidone, cyanate ester, polytetrafluo-roethylene (PTFE) or the like, for example.

As described hereinbefore, the organic gate dielectric layer 130 has to be used for the purpose of achieving the flexibility of the display device. However, the organic gate dielectric layer 130 is easily spoiled when forming the oxide semiconductor layer 140. Specifically, in one comparative example, the oxide semiconductor layer was formed through physical vapor deposition techniques. The deposition chamber was injected oxygen-containing gas to increase the mobility of the deposited oxide semiconductor layer, but the oxygen in the chamber would produce oxygen plasma in the depositing process. The oxygen plasma rapidly eroded the organic gate dielectric layer 130 and the gate electrode 120 was exposed. Consequently, a reliable oxide thin film transistor may not be manufactured. In another comparative example, no oxygen was injected into the deposition chamber when depositing the oxide semiconductor layer so as to avoid producing oxygen plasma. However, when depositing oxide semiconductor layer in an environment lacking oxygen, the mobility of the obtained oxide semiconductor layer was very low, and that in reality lost the advantage of using the oxide semiconductor. In still another comparative example, the oxide semiconductor layer was deposited in an oxygen-free environment, i.e. oxygen was not provided into the deposition chamber, and then the deposited oxide semiconductor layer was proceeded an annealing process at a high temperature (about 300° C. to about 400° C.) to increase the mobility of the deposited oxide semiconductor layer. Unfortunately, the organic gate dielectric layer 130 was deteriorated or degraded under such a high temperature, and consequently an applicable thin film transistor was not successfully manufactured. Accordingly, manufacturing a metal-oxide thin film transistor on a flexible substrate is difficult. The present disclosure is provided to overcome the difficulties occurred in many comparative examples.

According to various embodiments of the present disclosure, prior to forming the oxide semiconductor layer 140, the first passivation layer 150 is firstly formed. The first passivation layer 150 covers at least the portion of the organic gate dielectric layer 130 that is right above the gate electrode 120. When the oxide semiconductor layer is deposited in an oxygen-containing environment, the first passivation layer 150 is able to prevent the organic gate dielectric layer 130 thereunder from being eroded by the oxygen plasma in the deposition chamber, and therefore it overcomes the difficulties described in the comparative examples hereinbefore, and a metal-oxide thin film transistor is successfully manufactured on a flexible substrate. In addition, when the flexible substrate is bent, the first passivation layer 150 is not broken.

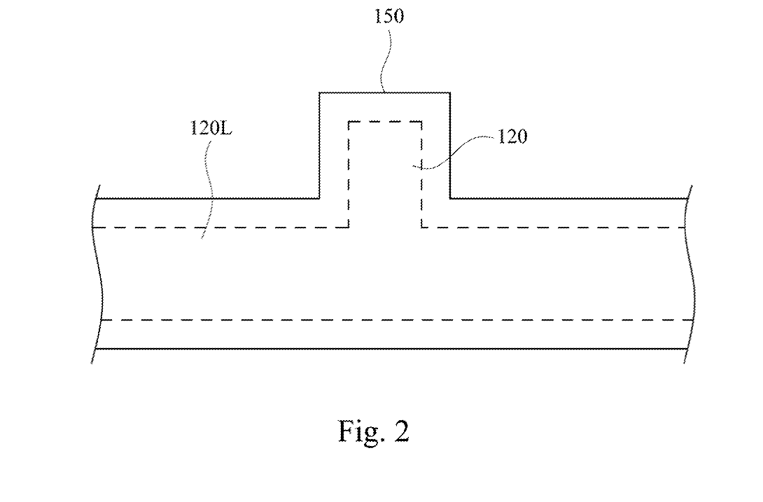

FIG. 2 is a top view schematically illustrating the first passivation layer 150, the gate electrode 120 and the gate line 120L according to one embodiment of the present disclosure. In this embodiment, when viewing in the direction D1 vertical to the flexible substrate 110, the first passivation layer 150 overlaps the gate electrode 120 and gate line 120L. In other words, the first passivation layer 150 covers at least the portion of the organic gate dielectric layer 130 that is right above the gate electrode 120 and gate line 120L.

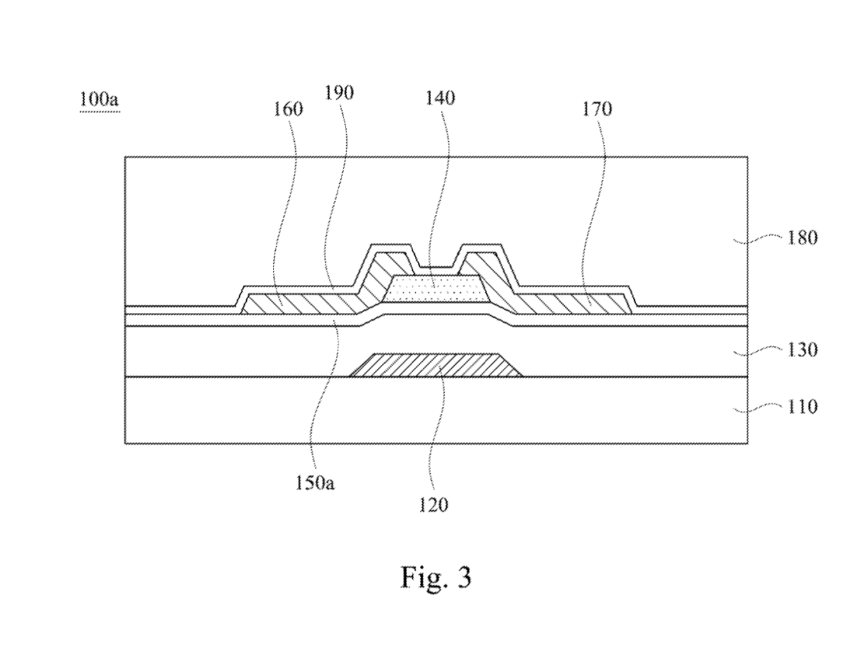

FIG. 3 is a cross-sectional view schematically illustrating an organic-inorganic hybrid transistor 100a according to various embodiments of the present disclosure. In FIG. 1 and FIG. 3, Like reference numerals denote like elements or features, and these elements or features may be referred to the embodiments described hereinbefore in connection with FIG. 1. Therefore, the description of these elements or features is omitted to avoid repetition.

According to some embodiments of the present disclosure, the organic-inorganic hybrid transistor 100a has a first passivation layer 150a that thoroughly covers the organic gate dielectric layer 130. In these embodiments, the first passivation layer 150a must have a bent deformation corresponding to the flexible substrate 110, so that the thickness of the first passivation layer 150a is limited to a certain range. When the thickness of the first passivation layer 150 is less than a certain value, for example, less than about 100 Angstrom (A), the first passivation layer 150a may not efficiently protect the organic gate dielectric layer 130. On the other hand, when the thickness of the first passivation layer 150a is greater than a certain value, for example, greater than about 1000 Angstrom (A), the first passivation layer 150a is broken and leads to the failure of the transistor 100 when the flexible substrate 110 is bent. As a result, according to some embodiments of the present disclosure, the thickness of the first passivation layer 150a is about 100 Angstrom (A) to about 1000 Angstrom (A), specifically, about 200 Angstrom (A) to about 800 Angstrom (A).

According to some embodiments of the present disclosure, the organic-inorganic hybrid transistor 100a further comprises a second passivation layer 190 capable of preventing the oxide semiconductor layer 140 from being unfavorably affected by the organic protective layer 180. The second passivation layer 190 is a passivation layer substantially made of inorganic material. The term “inorganic material” used herein, by meaning, comprises the inorganic material used in general chemistry field, and further comprises the glass film or ceramic film formed through sol-gel processes, i.e. sol-gel glass or sol-gel ceramics. These sol-gel glass or ceramics may contain some organic materials. The first passivation layer 150a and the second passivation layer 190 wrap up the oxide semiconductor layer 140, and separate it from the organic gate dielectric layer 130 and the organic protective layer 180 so to improve the stability of the oxide semiconductor layer 140. In one example, the second passivation layer 190 is disposed on and in contact with the source electrode 160, the drain electrode 170 and the oxide semiconductor layer 140. The second passivation layer 190 may comprise aluminum oxide, silicon oxide and silicon nitride or a combination thereof. For example, the second passivation layer 190 may be a single layer of aluminum oxide. Otherwise, the second passivation layer 190 may be a double-layered structure having a silicon oxide layer and a silicon nitride layer, in which the silicon oxide layer is situated at the bottom and in contact with the oxide semiconductor layer 140, the source electrode 160 and the drain electrode 170. In still another example, the second passivation layer 190 has a multiple-layered structure including at lest one aluminum oxide layer and at lest one silicon oxide layer, in which any one of the aluminum oxide layer and the silicon oxide layer may be situated at the bottom and in contact with the oxide semiconductor layer 140, source electrode 160 and drain electrode 170. In other examples, the second passivation layer 190 is a double-layered structure having a aluminum oxide layer and a silicon nitride layer, in which the aluminum oxide layer is situated at the bottom and in contact with the oxide semiconductor layer 140, source electrode 160 and drain electrode 170. According to one embodiment of the present disclosure, the first passivation layer 150 and the second passivation layer 190 respectively comprise a layer of aluminum oxide, and the first passivation layer 150 and the second passivation layer 190 are respectively about 100 Angstrom (A) to about 1000 Angstrom (A) in thickness.

In yet some embodiments, the second passivation layer 190 comprises a layer of sol-gel glass and/or sol-gel ceramic. For example, the sol-gel glass and/or ceramic may comprise boron-phosphor-silicate glass (BPSG), high silicon-content CaO-P₂O₅—SiO₂ glass or the like formed through the sol-gel process.

According to some embodiments of the present disclosure, the organic-inorganic hybrid transistor 100a further comprises an organic protective layer 180 covering the second passivation layer 190.

Although bottom-gate structures of the thin film transistors are illustrated in the embodiments described hereinbefore, the present disclosure is not limited thereto. More detailed description is provided hereinafter.

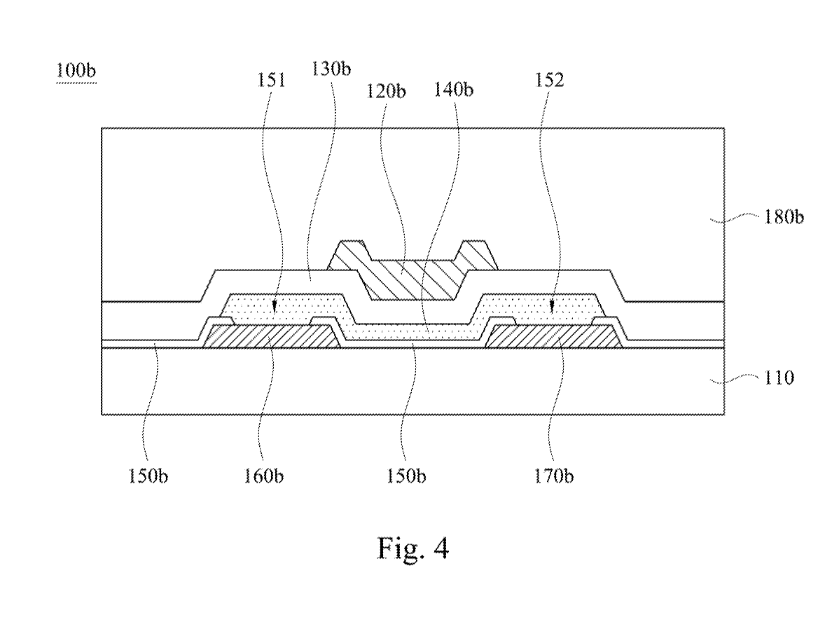

FIG. 4 is a cross-sectional view schematically illustrating an organic-inorganic hybrid transistor 100b according to some embodiments of the present disclosure. The organic-inorganic hybrid transistor 100b is a top-gate thin film transistor. The flexible substrate 110 may be made of an organic polymeric material. The source electrode 160b and the drain electrode 170b are disposed on the flexible substrate 110. The first passivation layer 150b is disposed on and in contact with the source electrode 160b, the drain electrode 170b and the flexible substrate 110. In one example, the first passivation layer 150b covers the exposed portion of the flexible substrate 110. Stated differently, the first passivation layer 150b covers the portion of the flexible substrate 110 that is not occupied by the source electrode 160b and the drain electrode 170b. Furthermore, the first passivation layer 150b has a first opening 151 and a second opening 152 respectively exposing a portion of the source electrode 160b and a portion of the drain electrode 170b. The oxide semiconductor layer 140b is disposed on the first passivation layer 150b, and two different sides of the oxide semiconductor layer 140b are respectively connected with the exposed portions of the source electrode 160b and the drain electrode 170b. The organic gate dielectric layer 130b is disposed over the oxide semiconductor layer 140b. The gate electrode 120b is disposed on the oxide semiconductor layer 140b. Consequently, the organic gate dielectric layer 130b is interposed between the gate electrode 120b and oxide semiconductor layer 140b. The organic protective layer 180b covers the gate electrode 120b and organic gate dielectric layer 130b.

It is noted that when the flexible substrate 110 is made of organic polymeric material, the flexible substrate 110 may be eroded or etched by the oxygen plasma generated in the deposition chamber when depositing the oxide semiconductor layer 140b, and leads to an unfavorable result. Therefore, according to some embodiments of the present disclosure, prior to forming the oxide semiconductor layer 140b, the first passivation layer 150b is firstly formed to cover at least a portion of the flexible substrate 110, which is not occupied by the source electrode 160b and the drain electrode 170b, to prevent the flexible substrate 110 from being eroded by the oxygen plasma generated in the process chamber of depositing the oxide semiconductor layer 140b. The material and other features of the first passivation layer 150b may be the same as these described hereinbefore in connection with the first passivation layer 150.

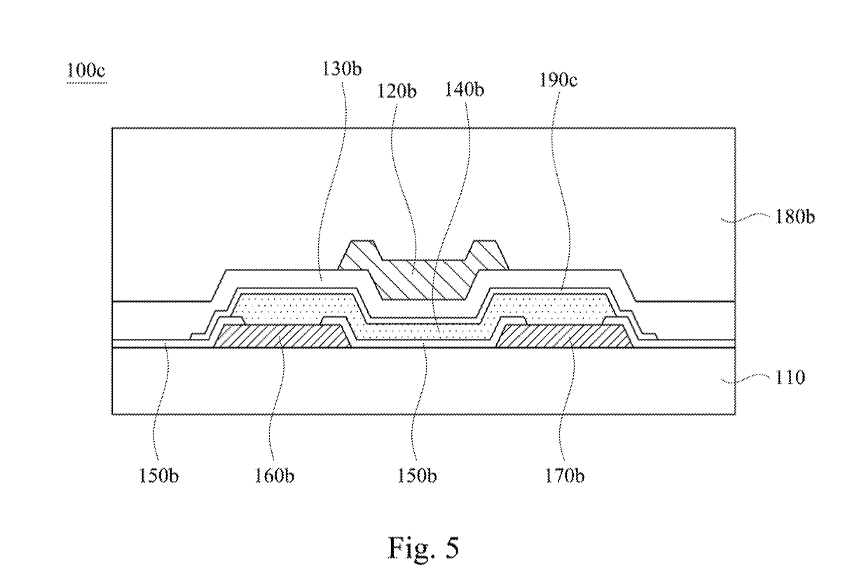

FIG. 5 is a cross-sectional view schematically illustrating an organic-inorganic hybrid transistor 100c according to another embodiment of the present disclosure. The organic-inorganic hybrid transistor 100c is generally similar to the transistor 100b depicted in FIG. 4 in structure, but the difference in between is that the organic-inorganic hybrid transistor 100c further comprises a second passivation layer 190c. The second passivation layer 190c is interposed between the organic gate dielectric layer 130b and oxide semiconductor layer 140b, and the second passivation layer 190c covers the oxide semiconductor layer 140b. The first passivation layer 150b and the second passivation layer 190c wrap up the oxide semiconductor layer 140b and separate it from the organic gate dielectric layer 130b and flexible substrate 110. The first passivation layer 150b and the second passivation layer 190c may facilitate to improve the stability of the oxide semiconductor layer 140b. The material and other features of the second passivation layer 190c may be the same as these described hereinbefore in connection with the second passivation layer 190.

It will be apparent to those skilled in the an that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An organic-inorganic hybrid transistor, comprising:
a flexible substrate;
a gate electrode disposed on the flexible substrate;
an organic gate dielectric layer covering the gate electrode and a portion of the flexible substrate;
an oxide semiconductor layer disposed over the organic gate dielectric layer, wherein the oxide semiconductor layer overlaps the gate electrode when viewed in a direction vertical to the flexible substrate;
a first passivation layer comprising an inorganic material, wherein the first passivation layer is interposed between and in contact with the oxide semiconductor layer and the organic gate dielectric layer; and
a source electrode and a drain electrode respectively connected to two different sides of the oxide semiconductor layer.

2. The organic-inorganic hybrid transistor according to claim 1, wherein the first passivation layer consists essentially of an inorganic material, and comprises at least one material selected from the group consisting of aluminum oxide, silicon oxide, silicon nitride and a combination thereof.

3. The organic-inorganic hybrid transistor according to claim 2, wherein the first passivation layer is about 100 Angstrom (A) to about 1000 Angstrom (A) in thickness.

4. The organic-inorganic hybrid transistor according to claim 1, wherein the first passivation layer comprises a material of sol-gel glass.

5. The organic-inorganic hybrid transistor according to claim 1, wherein the first passivation layer and the oxide semiconductor layer have a substantially identical pattern.

6. The organic-inorganic hybrid transistor according to claim 1, wherein the first passivation layer thoroughly covers the organic gate dielectric layer.

7. The organic-inorganic hybrid transistor according to claim 1, further comprising a second passivation layer disposed on and in contact with the source electrode, the drain electrode and the oxide semiconductor layer, wherein the second passivation layer comprises an inorganic material.

8. The organic-inorganic hybrid transistor according to claim 7, further comprising an organic protective layer covering the second passivation layer.

9. The organic-inorganic hybrid transistor according to claim 7, wherein the second passivation layer comprises at least one material selected from the group consisting of aluminum oxide, silicon oxide, silicon nitride and a combination thereof.

10. The organic-inorganic hybrid transistor according to claim 7, wherein the first passivation layer and the second passivation layer comprise aluminum oxide, and the first passivation layer and the second passivation layer are respectively about 100 Angstrom (A) to about 1000 Angstrom (A) in thickness.

11. An organic-inorganic hybrid transistor, comprising:
a flexible substrate;
a source electrode and a drain electrode disposed on the flexible substrate;
a first passivation layer in contact with and disposed on the source electrode, the drain electrode and the flexible substrate, wherein the first passivation layer has a first opening and a second opening respectively exposing a portion of the source electrode and a portion of the drain electrode;
an oxide semiconductor layer disposed on the first passivation layer, wherein the exposed portion of the source electrode and the exposed portion of the drain electrode are respectively connected to two different sides of the oxide semiconductor layer;
a gate electrode disposed over the oxide semiconductor layer; and
an organic gate dielectric layer interposed between the gate electrode and the oxide semiconductor layer.

12. The organic-inorganic hybrid transistor according to claim 11, further comprising a second passivation layer disposed between the organic gate dielectric layer and the oxide semiconductor layer, wherein the second passivation layer covers the oxide semiconductor layer.
